(19) United States
(12) Patent Application Publication
(10) Pub. No.: US 2008/0070355 A1
(43) Pub. Date: Mar. 20, 2008

(54) ASPECT RATIO TRAPPING FOR MIXED SIGNAL APPLICATIONS

(75) Inventors: Anthony J. Lochtefeld, Somerville, MA (US); James Fiorenza, Wilmington, MA (US)

Correspondence Address: GOODWIN PROCTER LLP;PATENT ADMINISTRATOR, EXCHANGE PLACE, BOSTON, MA, 02109-2881, US

(73) Assignee: AmberWave Systems Corporation, Salem, NH (US)

(21) Appl. No.: 11/857,047

(22) Filed: Sep. 18, 2007

Related U.S. Application Data
(60) Provisional application No. 60/845,303, filed on Sep. 18, 2006.

(51) Int. Cl. H01L 21/338

(52) U.S. Cl. 438/172; 257/E21.45

(57) ABSTRACT

Structures and methods for their formation include a substrate comprising a first semiconductor material, with a second semiconductor material disposed thereover, the first semiconductor material being lattice mismatched to the second semiconductor material. Defects are reduced by using an aspect ratio trapping approach.

### RELATED APPLICATIONS

This application claims the benefit of and priority to U.S. Provisional Application Ser. No. 60/845,303 filed Sep. 18, 2006, the disclosure of which is hereby incorporated by reference in its entirety.

### FIELD OF THE INVENTION

This invention relates generally to semiconductor processing and particularly to integration of mixed digital and analog devices.

### BACKGROUND OF THE INVENTION

Many (if not most) modern electronic devices incorporate both digital circuits and analog circuits. Devices such as cellular telephones, digital TV receivers, and computers perform both information processing and storage functions as well as communication functions. In these devices, the information processing and storage is performed primarily by digital circuits while the communication functions are accomplished using mostly analog circuits.

Historically, semiconductor technologies designed for digital functions have evolved separately from semiconductor technologies designed for analog functions. Silicon (Si) complementary metal-oxide-semiconductor field-effect transistors (CMOS FETs) have become the dominant digital technology, while numerous technologies have emerged for analog applications including Si bipolar junction transistors (BJT) and heterojunction bipolar transistors (HBTs), gallium arsenide (GaAs) HBTs, and indium phosphide (InP) HBTs and high-electron-mobility transistors (HEMTs). Fundamentally, the two different classes of semiconductor technologies (digital and analog) have evolved differently because digital circuits and analog circuits place different demands on semiconductor devices. For example, digital circuits benefit from devices designed to increase switching speed and reduce switching power. Analog circuits, on the other hand, typically need a high switching speed, but also may need a high voltage gain and low output resistance, low noise levels, high breakdown voltage and/or low on-resistance.

### SUMMARY OF THE INVENTION

Selective epitaxy is suitable for the integration of heterogeneous compound semiconductors on substrates incorporating lattice-mismatched materials, such as Si, due to its flexibility and relative simplicity in comparison to other compound semiconductor integration approaches. By allowing the introduction of the compound semiconductor material only where and when it is needed, complications to and restrictions of the CMOS front- and back-end processing are reduced.

The aspect ratio trapping (ART) process, in which defect-free lattice-mismatched material is formed as described in detail below, facilitates combination of a wide variety of materials using selective epitaxy, due to its capacity to handle extremely large lattice and thermal mismatch. Two key challenges to integration of compound semiconductors on Si are lattice mismatch and thermal mismatch; both of these challenges are addressed by ART technology.

ART and Lattice Mismatch: For the high-mobility compound semiconductor materials of greatest interest for high-performance electronic applications, lattice mismatch relative to Si typically ranges from 4% (for GaAs) up to ˜12-19% (for antimonide-based compound semiconductors). Growing such films directly on Si may lead to unacceptable dislocation defect levels. Taking GaAs as an example, growing more than a few nanometers (nm) directly on Si typically leads to a dislocation density of 10⁸-10⁹/cm² due to the lattice mismatch between the two materials. Such highly defective material is useful for only a few device applications. Much research on epitaxy for compound semiconductors on Si has involved blanket (i.e., wafer-scale) epitaxial buffer layers interposed between the substrate and the compound semiconductor device layers (most successfully, the graded buffer technology). For the case of large (≧4%) mismatch, current approaches for reducing defects significantly below 10⁸/cm² typically involve thick (≧10 micrometers (μm)) epitaxial layers. Requiring such vertical displacement between the Si and III-V devices is generally incompatible with Si CMOS technology, and may make interconnection between the Si and III-V devices impractical.

Selective approaches have had relatively greater success for fully strained layers such as the base region of HBTs, where the dislocation defects associated with plastic relaxation do not arise. Although there has been some hope in the past that strain in small selective epitaxial islands would drive dislocations to the pattern edge (thus eliminating them), in fact this tends not to work well for more than very small mismatch, due both to the predominance of sessile dislocations that cannot glide in response to strain and pinning interactions even between the mobile glissile dislocations. ART technology overcomes this limitation by relying on defect geometry instead of defect motion. For example, growing cubic semiconductors on a (100) Si surface leads to threading dislocations that tend to rise from the surface at 45°. Such dislocations will be trapped below the epitaxial surface if grown in a trench with an aspect ratio h/w>1, thereby providing a defect-free region suitable for device fabrication.

ART and Thermal Mismatch: Small selective regions on Si are far less subject to stresses resulting from mismatch between thermal expansion coefficients, in comparison to continuous layers (whether integrated with Si via epitaxy or via bonding). For example, for a 1 μm GaAs film grown on (or bonded to) a Si wafer at 600° C., the stress resulting from the 162% thermal mismatch will be on the order of 300 MPa. For a continuous film, this stress may only be accommodated by wafer bow or by some form of plastic relaxation, leading to defects. For the small regions of GaAs on Si that result from the ART process, however, such strain can be accommodated through elastic expansion or contraction of the ART region, allowed by the relative compliancy of the surrounding SiO₂.

ART and III-V HEMT technology: ART is especially well suited to FET technologies, because the entire active region length, including source, drain, and gate can be very short. A HEMT device may be fabricated on a strip of III-V material (GaAs or InP) just 1 μm wide. Since ART places a restriction on the dimension of an active region in only one direction (e.g., the length), such a HEMT device can be of arbitrary width. This is important in mixed-signal circuits for which large-width devices are preferred. From the standpoint of mixed-signal circuit performance, HEMT technology is very promising; InP-based HEMTs have an extremely high cut-off frequency (fₜ) for any transistor technology demonstrated to date—greater than 560 GHz, 10% higher then InP-based HBTs and far above any GaAs-based technologies.

By use of ART processes, a semiconductor technology is provided that is suitable for modern electronic devices that utilize both information processing and communication. Specialized analog semiconductor technologies may be integrated along with digital technology on the same semiconductor substrate. This integration facilitates fabrication of mixed-signal analog/digital devices with superior performance and low cost. The modular approach allows the separate optimization of both CMOS and III-V or II-VI device processes, such that neither process constrains the other. This may be achieved by, e.g., first performing CMOS front-end processing, then forming the III-V or II-VI structures, and thereafter finishing the CMOS structures with back-end processing.

In an aspect, the invention features a method for forming a structure, the method including forming a first device on a first portion of a substrate that includes a first semiconductor material. An epitaxial region is selectively formed on a second portion of the substrate. The second portion of the substrate is substantially free of overlap with the first portion of the substrate. The epitaxial region includes a second semiconductor material that is different from and lattice mismatched to the first semiconductor material. A second device is formed in the epitaxial region, and electrical communication is established between the first device and the second device.

One or more of the following features may be included. First and second openings may be defined in the substrate, such that the first device is formed in a region of the substrate proximate the first opening and the epitaxial region is formed in the second opening. A shallow trench isolation region may be defined in the first opening, e.g., by filling the first opening with a dielectric material including at least one of silicon dioxide, silicon nitride, or a low-k material.

In some embodiments, a dielectric material is disposed in the second opening, with the dielectric material defining a cavity having a sidewall. The ratio of the cavity height to the cavity width is selected such that dislocations in the epitaxial region are trapped by the sidewall of the cavity. The ratio of the cavity height to the cavity width may be greater than 0.5, and/or the height of the cavity may be selected from the range of 0.2 μm to 2 μm. The first device may include a metal-oxide-semiconductor field-effect transistor and the second device may include an analog transistor, e.g., a BJT, a MODFET, a HEMT, or a MESFET.

The first semiconductor material may include a group IV element, such as germanium or silicon, e.g., (100) silicon. The second semiconductor material may include at least one of (i) a group IV element, (ii) a III-V compound, such as gallium arsenide, gallium nitride, indium arsenide, indium antimonide, indium aluminum antimonide, indium aluminum arsenide, indium phosphide, or indium gallium arsenide, or a (iii) II-VI compound, such as zinc selenide or zinc oxide.

A first opening may be formed in the first portion of the substrate. Thereafter, an interlevel dielectric layer may be formed over the substrate; and a cavity defined in the interlevel dielectric layer over the second portion of the substrate. The first device is formed in a region of the substrate proximate the first opening and the epitaxial region is formed in the cavity. In an embodiment, a shallow trench isolation region may be defined in the first opening, e.g., by filling the first opening with a dielectric material including at least one of silicon dioxide, silicon nitride, or a low-k material.

The cavity may have a sidewall, and a ratio of a height of the cavity to a width of the cavity is selected such that dislocations in the epitaxial region are trapped by the sidewall of the cavity, e.g., the ratio is greater than 0.5. The height of the cavity may be selected from the range of 0.2 μm to 2 μm. In some embodiments, the first device is substantially co-planar with the second device.

In another aspect, the invention features a method for forming a structure including a region of lattice-mismatched semiconductor material disposed in an opening in a substrate. The method includes defining the opening in the substrate, which comprises a first semiconductor material. A dielectric material is disposed in the opening, the dielectric material defining a cavity having a sidewall. An epitaxial region is formed within the cavity, the epitaxial region comprising a second semiconductor material lattice-mismatched to the first semiconductor material. A ratio of a height of the cavity to a width of the cavity is selected such that a dislocation in the epitaxial region is trapped by the sidewall of the cavity.

In yet another aspect, the invention features a method for forming a structure. The method includes forming a first device over a first portion of a substrate, the substrate comprising a first semiconductor material having a first lattice constant. A region for epitaxial growth is defined over a second portion of the substrate, the second portion of the substrate being substantially free of overlap with the first portion of the substrate. The epitaxial growth region includes a bottom surface defined by a substrate surface and a sidewall including a non-crystalline material. An epitaxial material is selectively formed in the epitaxial growth region, the epitaxial material including a second semiconductor material having a second lattice constant different from the first lattice constant. A second device is formed, being disposed at least partially in the epitaxial growth region. Thereafter, electrical communication is established between the first device and the second device.

In another aspect, the invention features a method for integrating multiple transistor types on a silicon substrate, the method including forming a shallow trench isolation region in a substrate comprising silicon. A first transistor including a silicon channel region is formed proximate the shallow trench isolation region. An epitaxial growth region is formed proximate a substrate surface, the epitaxial growth region including (i) a bottom surface defined by a substrate surface, and (ii) a non-crystalline sidewall. A semiconductor material lattice mismatched to silicon is formed in the epitaxial growth region. A second transistor is formed above a bottom surface of the epitaxial growth region, the second transistor having a channel comprising at least a portion of the semiconductor material.

In still another aspect, the invention features a structure including multiple devices and lattice-mismatched semiconductor materials. A first device is formed over a first portion of a substrate comprising a first semiconductor material, the first device comprising a channel including at least a portion of the first semiconductor material. a second device formed over (i) an opening above a second portion of the substrate, the opening having a non-crystalline sidewall and (ii) a second semiconductor material lattice-mismatched to the first semiconductor material that is disposed within the opening and extends from the substrate to the second device.

In yet another aspect, the invention features a method for forming a structure. The method includes forming a first device on a first portion of a substrate, which includes a first semiconductor material. An epitaxial region is formed on a second portion of the semiconductor substrate. The epitaxial region includes a second semiconductor material that is different from the first semiconductor material. A second device is defined in the epitaxial region. Thereafter, an interconnect is formed between the first device and the second device.

One or more of the following features may be included. A first opening and a second opening may be defined in the substrate, such that the first device is formed in a region of the substrate proximate the first opening and the epitaxial region is formed in the second opening. A shallow trench isolation region may defined in the first opening. Defining the shallow trench isolation region may include filling the first opening with a dielectric material including at least one of silicon dioxide, silicon nitride, and a low-k material.

At least one dielectric material may be disposed in the second opening, the dielectric material defining a cavity having a sidewall, and a ratio of the cavity height to the cavity width is selected such that dislocations in the epitaxial region are trapped by the sidewall of the cavity. The ratio of the height of the cavity to the width of the cavity may be greater than 0.5. The height of the cavity may be selected from the range of 0.2 μm to 2 μm.

The first device may include a metal-oxide-semiconductor field-effect transistor and the second device may include an analog transistor, such as a BJT, a MODFET, a HEMT, or a MESFET.

The first semiconductor material may include a group IV element, such as germanium and/or silicon, e.g., (100) silicon, and the second semiconductor material may include at least one of a group IV element, a III-V compound, and a II-VI compound.

The III-V compound may include at least one of gallium arsenide, gallium nitride, indium arsenide, indium antimonide, indium aluminum antimonide, indium aluminum arsenide, indium phosphide, and indium gallium arsenide. The II-VI compound may include at least one of zinc selenide and zinc oxide.

The method may include defining a first opening in a first portion of the substrate, forming an interlevel dielectric layer over the substrate, and defining a cavity in the dielectric layer over a second portion of the substrate. The first device may be formed in a region of the substrate proximate the first opening and the epitaxial region may be formed in the cavity.

A shallow trench isolation region may be defined in the first opening. Defining the shallow trench isolation region may include filling the first opening with a dielectric material including at least one of silicon dioxide, silicon nitride, and a low-k material.

The cavity may have a sidewall, and a ratio of a height of the cavity to a width of the cavity may be selected such that dislocations in the epitaxial region are trapped by the sidewall of the cavity. The ratio of the height of the cavity to the width of the cavity may be greater than 0.5. The height of the cavity may be selected from the range of 0.2 μm to 2 μm.

### BRIEF DESCRIPTION OF THE DRAWINGS

In the drawings, like reference characters generally refer to the same features throughout the different views. Also, the drawings are not necessarily to scale, emphasis instead being placed upon illustrating the principles of the invention.

FIGS. 1-8b are schematic cross-sectional views illustrating a method for formation of devices on a semiconductor substrate; and

FIGS. 9-15 are schematic cross-sectional views illustrating an alternative method for formation of devices on a semiconductor substrate.

### DETAILED DESCRIPTION

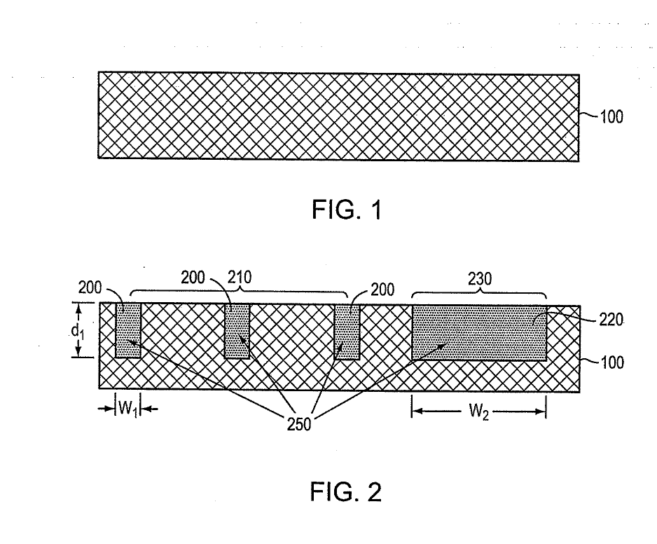

Referring to FIG. 1, a substrate 100 includes a crystalline semiconductor material. The substrate 100 may be, for example, a bulk silicon wafer, a bulk germanium wafer, a semiconductor-on-insulator (SOI) substrate, or a strained semiconductor-on-insulator (SSOI) substrate. The substrate 100 may include or consist essentially of a first semiconductor material, such as a group IV element, e.g., germanium or silicon. In an embodiment, substrate 100 includes or consists essentially of (100) silicon.

ART is used to create a relatively defect-free portion of an epitaxial region disposed in an opening over the substrate. As used herein, ART refers generally to the technique(s) of causing defects to terminate at non-crystalline, e.g., dielectric sidewalls, where the sidewalls are sufficiently high relative to the size of the growth area so as to trap most, if not all, of the defects. This technology allows the growth of an epitaxial material directly in contact with a lattice-mismatched substrate, substantially eliminating epitaxial growth defects by taking advantage of defect geometry in confined spaces.

Referring to FIG. 2, a plurality of first openings 200 (three are illustrated) is defined in a first portion 210 of the substrate 100 and a second opening 220 is defined in a second portion 230. The second portion 230 of the substrate 100 is substantially free of overlap with the first portion 210 of the substrate. A mask (not shown), such as a photoresist mask, is formed over the substrate 100. The mask is patterned to expose at least a first region and a second region of substrate 100. The exposed regions of the substrate are removed by, e.g., reactive ion etching (RIE) to define the first opening 200 and the second opening 220. The first opening 200 may have dimensions suitable for use as a shallow trench isolation region, e.g., a width w₁ of, e.g., 0.2-1.0 μm and a depth d₁ of, e.g., 0.2-0.5 μm. The second opening 220 may have dimensions suitable for the formation of a device, such as an analog transistor, e.g., a width w₂ of, e.g., 0.5-5 μm and a depth d₁ of, e.g., 0.2-2.0 μm

Openings 200 and 220 are filled with a dielectric material 250, in accordance with shallow trench isolation formation methods known to those of skill in the art. Dielectric material 250 may include or consist essentially of silicon dioxide, silicon nitride, and/or a low-k dielectric.

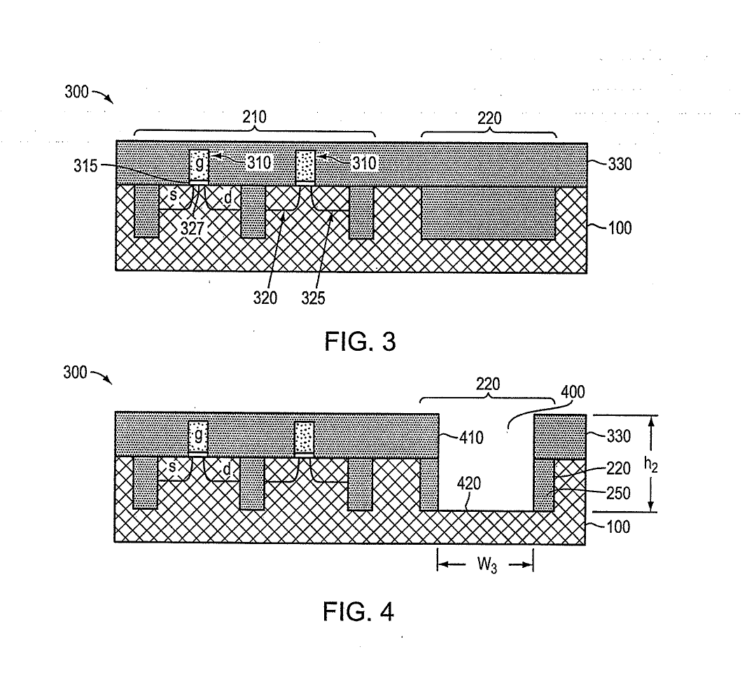

Referring to FIG. 3, a first device 300 is formed on the first portion 210 of the substrate 100. The first device 300 may be, e.g., a transistor, such as an n-type MOSFET (nMOSFET) or a p-type MOSFET (pMOSFET). In an embodiment, the first device 300 may be a CMOS device. Forming a MOSFET may include defining a gate electrode 310 over a gate dielectric 315, a source region 320, and a drain region 325 in accordance with methods known to those of skill in the art. The MOSFET includes a channel 327 disposed underneath the gate electrode 310. The channel 327 lies within portion 210 and includes or consists essentially of the first semiconductor material, e.g., the channel 327 may include silicon. The first device may be formed proximate the shallow trench isolation region defined in opening 200.

After the first device 300 is defined, an interlevel dielectric layer 330 may be deposited over the entire substrate 100, including over the first portion 210 and the second portion 220. The interlevel dielectric may include a dielectric materials such as, for example, SiO₂ deposited by, e.g., chemical vapor deposition (CVD). The interlevel dielectric layer 330 may be planarized by, e.g., chemical-mechanical polishing (CMP).

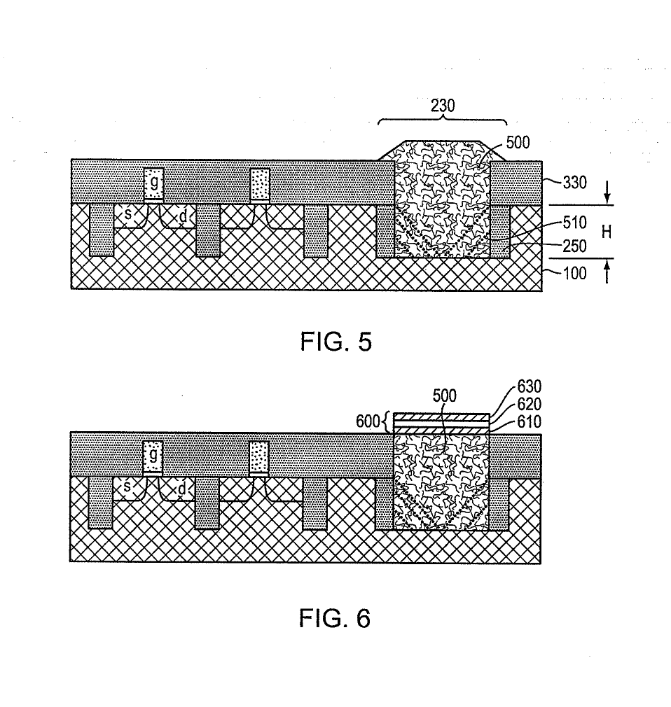

Referring to FIG. 4, an epitaxial growth region is defined by forming a cavity 400 in interlevel dielectric layer 330 and in the dielectric material 250 disposed in opening 220 in portion 230 of substrate 100. Cavity 400 has a non-crystalline sidewall 410 and may extend to the bottom surface 420 of the second opening 220, such that a bottom portion of the cavity 400 is defined by a surface of the substrate 100, i.e., the epitaxial growth region includes a bottom surface defined by the substrate surface and a sidewall including a non-crystalline material. The height h₂ of the cavity may be selected from a range of, for example, 0.2 μm to 2 μm. As discussed below with reference to FIG. 5, the ratio of the height h₂ of the cavity 400 to the width w₃ of the cavity 400 is selected such that dislocations in an epitaxial material disposed in the cavity 400 are trapped by a sidewall of the cavity. The ratio of the height h₂ of the cavity 400 to the width w₃ of the cavity may be greater than 0.5.

The structure shown in FIG. 4, including the first device 300 and the cavity 400 defined in the interlevel dielectric layer 330 and in the dielectric material 250 disposed in the opening 220 formed in the substrate 100, is preferably made in a CMOS foundry using a standard CMOS process flow. High-density, high-performance CMOS devices may be made in the foundry.

Referring to FIG. 5, an epitaxial region 500 is formed on the second portion 230 of the semiconductor substrate 100. The epitaxial region 500 includes or consists essentially of a second semiconductor material that may be lattice mismatched to the first semiconductor material, i.e., a lattice constant of the first semiconductor material may be different form a lattice constant of the second semiconductor material. For example, the second semiconductor material may be lattice mismatched to silicon in an embodiment in which the substrate includes silicon. The second semiconductor material may include or consist of a group IV element or compound, a III-V compound, or a II-VI compound. Examples of suitable III-V compounds include gallium arsenide, gallium nitride, indium arsenide, indium antimonide, indium aluminum antimonide, indium aluminum arsenide, indium phosphide, and indium gallium arsenide. Examples of suitable II-VI compounds include zinc selenide and zinc oxide.

The epitaxial region 500 may be formed by selective epitaxial growth in any suitable epitaxial deposition system, including, but not limited to, metal-organic chemical vapor deposition (MOCVD), atmospheric-pressure CVD (APCVD), low- (or reduced-) pressure CVD (LPCVD), ultra-high-vacuum CVD (UHCVD), molecular beam epitaxy (MBE), or by atomic layer deposition (ALD). In the CVD process, selective epitaxial growth typically includes introducing a source gas into the chamber. The source gas may include at least one precursor gas and a carrier gas, such as, for example, hydrogen. The reactor chamber may be heated by, for example, RF-heating. The growth temperature in the chamber may range from about 300° C. to about 900° C., depending on the composition of the epitaxial region. The growth system may also utilize low-energy plasma to enhance the layer growth kinetics.

The epitaxial growth system may be a single-wafer or multiple-wafer batch reactor. Suitable CVD systems commonly used for volume epitaxy in manufacturing applications include, for example, an Aixtron 2600 multi-wafer system available from Aixtron, based in Aachen, Germany; an EPI CENTURA single-wafer multi-chamber systems available from Applied Materials of Santa Clara, Calif.; or EPSILON single-wafer epitaxial reactors available from ASM International based in Bilthoven, The Netherlands.

Threading dislocations 510 in the epitaxial region 500 reach and terminate at the sidewalls of the cavity in the dielectric material 250 at or below a vertical predetermined distance H from the surface of the substrate, such that dislocations in the epitaxial region decrease in density with increasing distance from the bottom portion of the cavity. The height h₂ of the cavity may be at least equal to the predetermined vertical distance H from the substrate surface. For a semiconductor grown epitaxially in this opening, where the lattice constant of the semiconductor differs from that of the substrate, it is possible to trap crystalline defects in the epitaxial region at the epitaxial layer/sidewall interface, within the vertical predetermined distance H, when the ratio of h₂ to the width w₃ of the cavity is properly chosen. Accordingly, the bottom portion of the epitaxial region comprises defects, and the upper portion of the epitaxial region is substantially exhausted of threading dislocations. Other dislocation defects such as stacking faults, twin boundaries, or anti-phase boundaries may be substantially eliminated from the upper portion of the epitaxial region in a similar manner.

Referring to FIG. 6, a top portion of the epitaxial region 500 is planarized. In some embodiments, one or more epitaxial layers 600, suitable for some types of III-V devices, may be grown over the epitaxial region 500. For example, as illustrated for the case of a HEMT device, epitaxial layers 600 may include a buffer layer 610 including, e.g., InAlAs, a channel layer 620 including, e.g., InGaAs, and a barrier layer 630 including, e.g., InAlAs. The total thickness of the epitaxial layers 600 may be e.g. 50-500 nm. The growth of epitaxial layers 600 may be by, e.g., selective epitaxy.

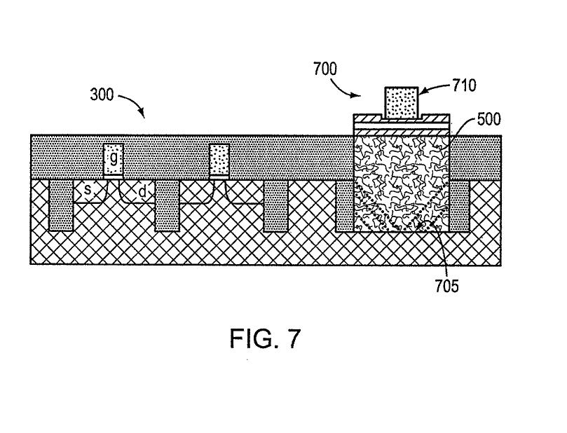

Referring to FIG. 7, a second device 700 is defined in the epitaxial region 500 such that the device 700 is disposed above a bottom surface 705 of the epitaxial region 500. In some embodiments, the thickness of the epitaxial region 500 is selected such that the first device 300 is substantially co-planar with the second device 700. The second device 700 may be an analog transistor, such as a BJT (for example, a HBT device), or a FET (for example, a MESFET or a HEMT device). The second device may include at least a portion of the second semiconductor material disposed in the epitaxial region 500, e.g., the second device may be a transistor having a channel including at least a portion of the second semiconductor material. The second device may include a gate 710.

The fabrication steps illustrated in FIGS. 5-7 may be performed in a specialized III-V device growth and fabrication facility. The CMOS processing steps (FIGS. 1-3) are optimally performed in a CMOS fabrication facility, enabling the creation of high-density, high-performance CMOS devices. However the fabrication processes in FIGS. 5-7, including epitaxy growth and III-V device fabrication, generally require tools and expertise different from those typically found in CMOS foundries. III-V epitaxial growth and III-V device fabrication may be performed in a specialized III-V fabrication facility that is typically separate from a CMOS foundry.

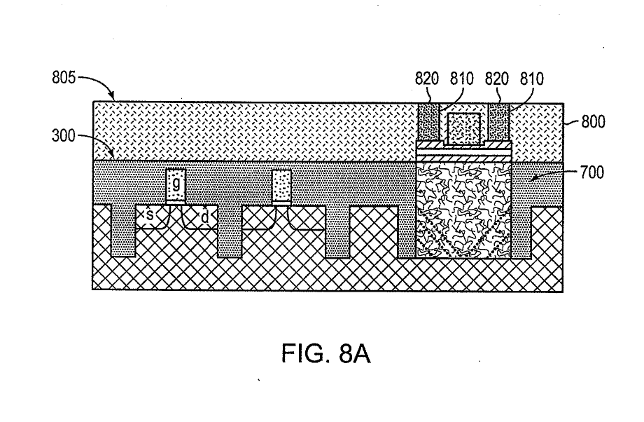

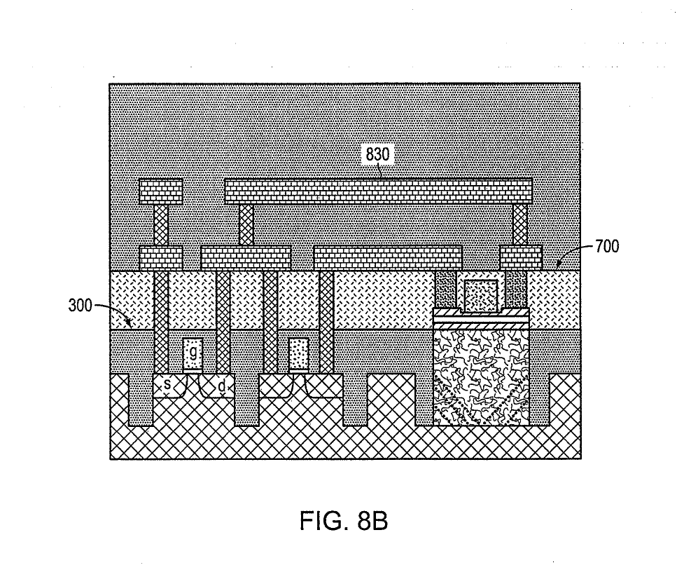

An interface process is performed after the formation of the first and second devices, e.g., CMOS and III-V devices, as depicted in FIG. 8a. The interface process is designed to establish electrical communication between the III-V device and the interconnects defined by a standard CMOS back-end process. A first interlevel dielectric layer 800 is deposited over the first and second devices 300, 700. The top surface 805 of the structure is planarized by, e.g., CMP. Holes 810 are etched through the dielectric layer 800 to the second device 700, e.g., a III-V device, and the holes 810 are filled with a metal 820. any suitable type of conductive metal may be used, e.g., gold, copper, aluminum, or tungsten. The interface process may be performed in a III-V facility or in a CMOS foundry.

Referring to FIG. 8b, further processing steps may be performed to establish electrical communication between the first device 300 and the second device 700 by, e.g., forming an interconnect 830. The formation of the interconnect 830 may include suitable device interconnect technologies to interface the second device 700, e.g., a III-V device to the first device 300, e.g., a Si CMOS device. Formation of the interconnect 830 may include forming contact holes in the first interlevel dielectric layer, depositing a first metallic interconnect layer that contacts the first device, forming a second interlevel dielectric layer, and depositing a second metallic interconnect layer that contacts the second device and the first metallic interconnect layer.

The process shown in FIG. 8b is preferably performed in a CMOS foundry. The back-end process steps, e.g., metal deposition, dielectric deposition, and metal patterning, are highly evolved in CMOS foundries, whereas the back-end processes in III-V device fabrication facilities are relatively primitive. Performing the back-end processes in a CMOS foundry permits the creation of high density, highly reliable back-end interconnects between the CMOS devices themselves, between the CMOS devices and the III-V devices, and between the III-V devices.

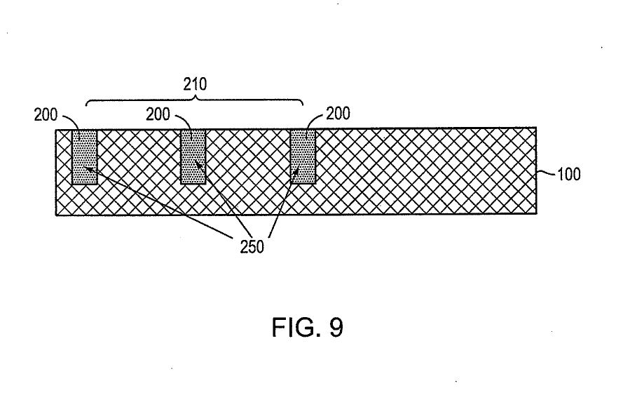

Referring to FIG. 9, in an alternative embodiment, first opening 200 is defined in the first portion 210 of the substrate 100. A mask (not shown), such as a photoresist mask, is formed over the substrate 100. The mask is patterned to expose at least a first region of substrate 100. The exposed region of the substrate is removed by, e.g., RIE to define the first opening 200. Opening 200 is filled with dielectric material 250.

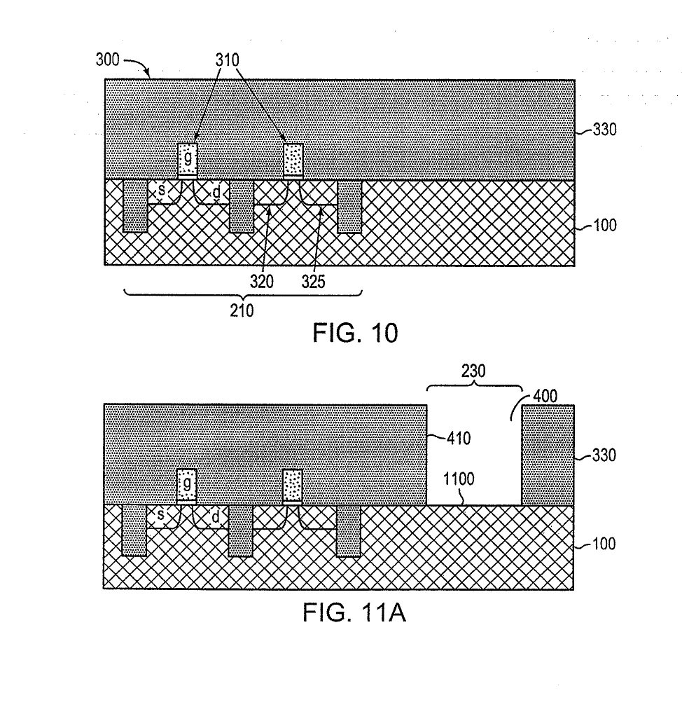

Referring to FIG. 10, the first device 300 is formed on the first portion 210 of the substrate 100.

After the first device 300 is defined, interlevel dielectric layer 330 may be deposited over the entire substrate 100, including over the first portion 210. The interlevel dielectric layer 330 may be planarized by, e.g., CMP.

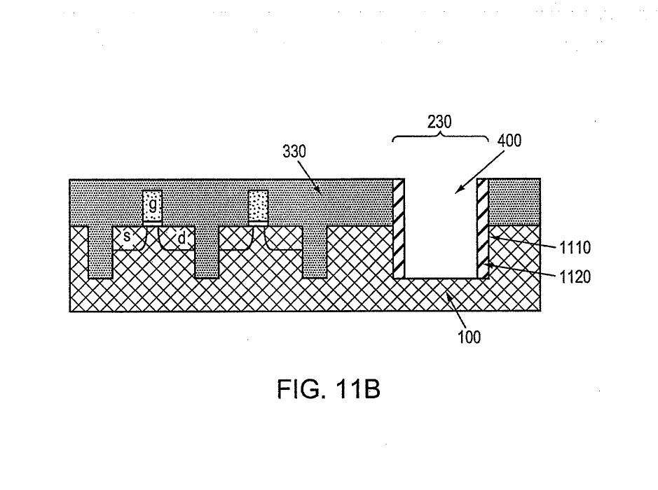

Referring to FIG. 11a, cavity 400 is defined in interlevel dielectric layer 330 over portion 230 of substrate 100. Cavity 400 has a sidewall 410 and may extend to a top surface 1100 of the substrate 100, such that a bottom portion of the cavity 400 is defined by the surface of the substrate 100. The height and width of the cavity are selected in accordance with the criteria discussed above with reference to FIG. 4.

An alternative method for forming the cavity 400 for epitaxial material growth is shown in FIG. 11b. Cavity 400 is defined in interlevel dielectric layer 330 over portion 230 of substrate 100. In an embodiment, the cavity 400 having a sidewall 1110 extends into the substrate 100. A spacer 1120 is formed, by depositing and anisotropically etching a thin dielectric layer, to cover the sidewall 1110 and prevent growth of epitaxial material thereon in the subsequent growth process. This process may enable the reproducible formation of sidewall spacers 1120 with a small thickness, e.g., as thin as 5 nm.

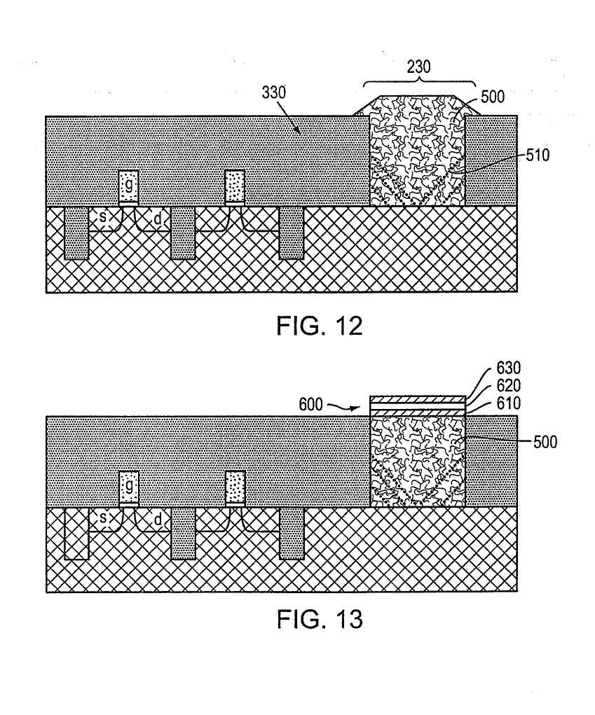

Referring to FIG. 12, epitaxial region 500 is formed on the second portion 230 of the semiconductor substrate 100.

Threading dislocations 510 in the epitaxial region 500 reach and terminate at the sidewalls of the cavity in the interlevel dielectric layer 330 at or below a predetermined distance H from the surface of the substrate, such that dislocations in the epitaxial region decrease in density with increasing distance from the bottom portion of the cavity. Accordingly, the upper portion of the epitaxial region is substantially exhausted of threading dislocations. Other dislocation defects such as stacking faults, twin boundaries, or anti-phase boundaries may be substantially eliminated from the upper portion of the epitaxial region in a similar manner.

Referring to FIG. 13, the top portion of the epitaxial region 500 is planarized. In some embodiments, one or more epitaxial layers 600, suitable for some types of III-V devices, may be grown over the epitaxial region 500. For example, in the case of a HEMT device, epitaxial layers 600 may include buffer layer 610 including, e.g., InAlAs, channel layer 620 including, e.g., InGaAs, and barrier layer 630 including, e.g., InAlAs. The total thickness of the epitaxial layers 600 may be, e.g. 50-500 nm. The growth of epitaxial layers 600 may be by e.g., selective epitaxy.

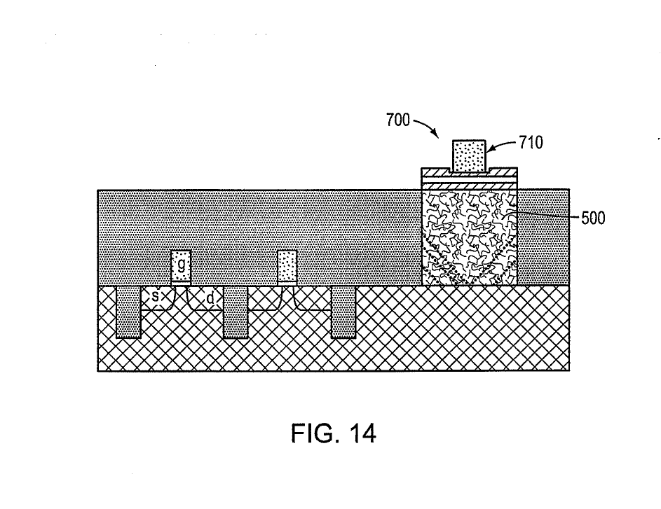

Referring to FIG. 14, second device 700 is defined in the epitaxial region 500. The second device may include gate 710. The second device 700 may be an analog transistor, such as a BJT (for example, an HBT device), or an FET (for example, a MESFET or a HEMT device).

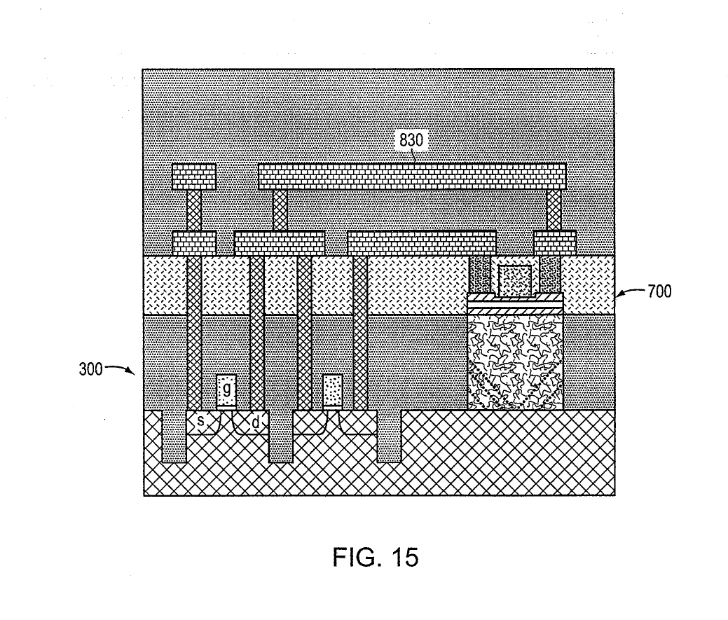

Referring to FIG. 15, further processing steps may be performed to establish electrical communication between the first device 300 and the second device 700 by, e.g., forming interconnect 830. The formation of the interconnect may include customized device interconnect technologies to interface the second device, e.g., a III-V device, to the first device, e.g., a Si CMOS device.

The invention may be embodied in other specific forms without departing from the spirit or essential characteristics thereof. The foregoing embodiments are therefore to be considered in all respects illustrative rather than limiting on the invention described herein. Scope of the invention is thus indicated by the appended claims rather than by the foregoing description, and all changes which come within the meaning and range of equivalency of the claims are intended to be embraced therein.

What is claimed is:

1. A method for forming a structure, the method comprising the steps of:
forming a first device on a first portion of a substrate, the substrate comprising a first semiconductor material;
selectively forming an epitaxial region on a second portion of the substrate, the second portion of the substrate being substantially free of overlap with the first portion of the substrate, the epitaxial region comprising a second semiconductor material different from and lattice mismatched to the first semiconductor material;
defining a second device in the epitaxial region; and
thereafter establishing electrical communication between the first device and the second device.

2. The method of claim 1, further comprising:
defining a first opening and a second opening in the substrate,
wherein the first device is formed in a region of the substrate proximate the first opening and the epitaxial region is formed in the second opening.

3. The method of claim 2, wherein a shallow-trench isolation region is defined in the first opening.

4. The method of claim 3, wherein defining the shallow-trench isolation region comprises filling the first opening with a dielectric material including at least one of silicon dioxide, silicon nitride, or a low-k material.

5. The method of claim 2, wherein at least one dielectric material is disposed in the second opening, the dielectric material defines a cavity having a sidewall, and a ratio of a height of the cavity to a width of the cavity is selected such that dislocations in the epitaxial region are trapped by the sidewall of the cavity.

6. The method of claim 5, wherein the ratio of the height of the cavity to the width of the cavity is greater than 0.5.

7. The method of claim 5, wherein the height of the cavity is selected from the range of 0.2 μm to 2 μm.

8. The method of claim 1, wherein the first device comprises a metal-oxide-semiconductor field-effect transistor and the second device comprises an analog transistor.

9. The method of claim 8, wherein the analog transistor is selected from the group consisting of a BJT, a MODFET, a HEMT, and a MESFET.

10. The method of claim 1, wherein the first semiconductor material comprises a group IV element and the second semiconductor material comprises at least one of a group IV element, a III-V compound, or a II-VI compound.

11. The method of claim 10, wherein the first semiconductor material comprises at least one of germanium or silicon.

12. The method of claim 11, wherein silicon comprises (100) silicon.

13. The method of claim 10, wherein the III-V compound includes at least one of gallium arsenide, gallium nitride, indium arsenide, indium antimonide, indium aluminum antimonide, indium aluminum arsenide, indium phosphide, or indium gallium arsenide.

14. The method of claim 10, wherein the II-VI compound includes at least one of zinc selenide or zinc oxide.

15. The method of claim 1, further comprising:
defining a first opening in the first portion of the substrate;
forming an interlevel dielectric layer over the substrate; and
defining a cavity in the interlevel dielectric layer over the second portion of the substrate,
wherein the first device is formed in a region of the substrate proximate the first opening and the epitaxial region is formed in the cavity.

16. The method of claim 15, wherein a shallow trench isolation region is defined in the first opening.

17. The method of claim 16, wherein defining the shallow trench isolation region comprises filling the first opening with a dielectric material including at least one of silicon dioxide, silicon nitride, or a low-k material.

18. The method of claim 15, wherein the cavity has a sidewall, and a ratio of a height of the cavity to a width of the cavity is selected such that dislocations in the epitaxial region are trapped by the sidewall of the cavity.

19. The method of claim 18, wherein the ratio of the height of the cavity to the width of the cavity is greater than 0.5.

20. The method of claim 18, wherein the height of the cavity is selected from the range of 0.2 μm to 2 μm.

21. The method of claim 1, wherein the first device is substantially co-planar with the second device.

22. A method for forming a structure including a region of lattice-mismatched semiconductor material disposed in an opening in a substrate, the substrate comprising a first semiconductor material, the method comprising the steps of:
disposing a dielectric material in the opening, the dielectric material defining a cavity having a sidewall; and
forming an epitaxial region within the cavity, the epitaxial region comprising a second semiconductor material lattice-mismatched to the first semiconductor material,
wherein a ratio of a height of the cavity to a width of the cavity is selected such that a dislocation in the epitaxial region is trapped by the sidewall of the cavity.

23. A method for forming a structure, the method comprising the steps of:
forming a first device over a first portion of a substrate, the substrate comprising a first semiconductor material having a first lattice constant;
defining a region for epitaxial growth over a second portion of the substrate, the second portion of the substrate being substantially free of overlap with the first portion of the substrate, the epitaxial growth region including a bottom surface defined by a substrate surface and a sidewall comprising a non-crystalline material;
selectively forming an epitaxial material in the epitaxial growth region, the epitaxial material comprising a second semiconductor material having a second lattice constant different from the first lattice constant;
forming a second device disposed at least partially in the epitaxial growth region; and
thereafter establishing electrical communication between the first device and the second device.

24. A method for integrating multiple transistor types on a silicon substrate, the method comprising:
forming a shallow trench isolation region in a substrate comprising silicon;
forming a first transistor comprising a silicon channel region proximate the shallow trench isolation region;
forming an epitaxial growth region proximate the substrate, the epitaxial growth region comprising (i) a bottom surface defined by a surface of the substrate, and (ii) a non-crystalline sidewall;
forming a semiconductor material lattice mismatched to silicon in the epitaxial growth region; and
forming a second transistor above the bottom surface of the epitaxial growth region, the second transistor having a channel comprising at least a portion of the semiconductor material.

25. A structure including a plurality of devices and lattice-mismatched semiconductor materials, the structure comprising:
a first device formed over a first portion of a substrate comprising a first semiconductor material, the first device comprising a channel including at least a portion of the first semiconductor material; and
a second device formed over (i) an opening above a second portion of the substrate, the opening having a non-crystalline sidewall and (ii) a second semiconductor material lattice-mismatched to the first semiconductor material that is disposed within the opening and extends from the substrate to the second device.
